(19) United States
(12) Patent Application Publication
(10) Pub. No.: US 2026/0075977 A1
(43) Pub. Date: Mar. 12, 2026

(54) IMAGE SENSING DEVICE

(71) Applicant: SK hynix Inc., Icheon-si (KR)

(72) Inventor: Sie Uoo KIM, Icheon-si (KR)

(21) Appl. No.: 19/240,690

(22) Filed: Jun. 17, 2025

(30) Foreign Application Priority Data
Sep. 10, 2024 (KR) 10-2024-0123356

(51) Int. Cl. H10F 39/00; H04N 25/77

(52) U.S. Cl. CPC H10F 39/811; H04N 25/77; H10F 39/8037

(57) ABSTRACT

An image sensing device includes at least one floating diffusion region configured to store photocharges; a first conductive line electrically connected to the at least one floating diffusion region; at least one boosting electrode configured to receive a boosting signal and disposed adjacent to the first conductive line; and at least one reverse boosting electrode disposed adjacent to the first conductive line and configured to receive a reverse boosting signal having an opposite phase to the boosting signal.

### PRIORITY AND CROSS-REFERENCE TO RELATED APPLICATION

This patent document claims the priority and benefits of Korean patent application No. 10-2024-0123356, filed on Sep. 10, 2024, which is incorporated by reference in its entirety as part of the disclosure of this patent document.

### TECHNICAL FIELD

The technology and implementations disclosed in this patent document generally relate to an image sensing device.

### BACKGROUND

An image sensor is a device for capturing optical images by converting light into electrical signals using a photosensitive semiconductor material which reacts to light. With the recent development of automotive, medical, computer and communication industries, the demand for high-performance image sensors is increasing in various fields such as smartphones, digital cameras, camcorders, personal communication systems (PCSs), game consoles, IoT (Internet of Things), robots, surveillance cameras, medical micro cameras, etc.

### SUMMARY

Various embodiments of the disclosed technology relate to an image sensing device capable of minimizing occurrence of signal errors caused by dark leakage sources.

In accordance with an embodiment of the disclosed technology, an image sensing device may include at least one floating diffusion region configured to store photocharges; a first conductive line electrically connected to the at least one floating diffusion region; at least one boosting electrode configured to receive a boosting signal and disposed adjacent to the first conductive line; and at least one reverse boosting electrode disposed adjacent to the first conductive line and configured to receive a reverse boosting signal having an opposite phase to the boosting signal.

In accordance with another embodiment of the disclosed technology, an image sensing device may include a first floating diffusion region and a second floating diffusion region, each of the first floating diffusion region and the second floating diffusion region configured to store photocharges; a plurality of first unit pixels disposed at different locations adjacent to the first floating diffusion region, and configured to generate the photocharges that are generated through a photoelectric conversion in each first unit pixel and are transferred to the first floating diffusion region; a plurality of second unit pixels disposed at different locations adjacent to the second floating diffusion region, and configured to generate photocharges that are generated through a photoelectric conversion in each second unit pixel and are transferred to the second floating diffusion region; a first conductive line configured to electrically interconnect the first floating diffusion region and the second floating diffusion region to form a common floating diffusion node; at least one boosting electrode disposed adjacent to the first conductive line, and configured to receive a boosting signal; and at least one reverse boosting electrode disposed adjacent to the first conductive line, and configured to receive a reverse boosting signal having an opposite phase to the boosting signal.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device according to an embodiment of the disclosed technology.

FIG. 2 is a circuit diagram illustrating an example of an equivalent circuit of a pixel block according to an embodiment of the disclosed technology.

FIG. 3 is a schematic diagram illustrating an example structure of a pixel block based on some implementations of the disclosed technology.

FIG. 4 is a plan view illustrating an example of a layout structure of photoelectric conversion elements, floating diffusion regions, and transistors shown in FIG. 3 according to an embodiment of the disclosed technology.

FIG. 5 is a timing diagram illustrating example operations of the image sensing device according to an embodiment of the disclosed technology.

FIG. 6 is a schematic diagram illustrating potential changes of a photoelectric conversion element, a transfer transistor, a common floating diffusion node, and a reset transistor for use in the operation sections of FIG. 5 according to an embodiment of the disclosed technology.

FIG. 7 is a schematic diagram illustrating an example structure of a boosting line and a reverse boosting line according to another embodiment of the disclosed technology.

FIG. 8 is a schematic diagram illustrating an example structure of a boosting line and a reverse boosting line according to another embodiment of the disclosed technology.

FIG. 9 is a schematic diagram illustrating an example structure of a boosting line and a reverse boosting line according to another embodiment of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an imagen sensing device capable of minimizing occurrence of signal errors caused by dark leakage sources. The disclosed technology provides various implementations of the image sensing device that can minimize occurrence of signal errors caused by dark leakage source.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

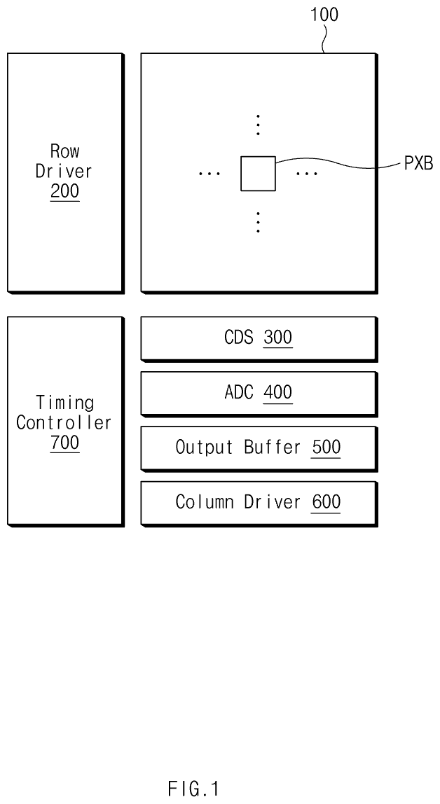

FIG. 1 is a block diagram illustrating an example of an image sensing device according to an embodiment of the disclosed technology.

Referring to FIG. 1, the image sensing device may include a pixel array 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of pixel blocks (PXBs) consecutively arranged in a two-dimensional (2D) matrix (including an X-axis direction and a Y-axis direction perpendicular to the X-axis direction). Each pixel block (PXB) may include a plurality of unit pixels configured to share a floating diffusion region (FD) with each other. For example, the pixel block (PXB) may be formed as an 8-shared pixel structure in which four unit pixels share one floating diffusion region and the remaining four unit pixels share the other floating diffusion region, the two floating diffusion regions (FD) are connected to each other through a conductive line to form a common floating diffusion node.

The unit pixels of the pixel block (PXB) may share a reset transistor, a source follower transistor, a selection transistor, and a conversion gain transistor. Each unit pixel may photoelectrically convert incident light into a pixel signal corresponding to the incident light, and may then output the pixel signal to a correlated double sampler (CDS) 200 through column lines. Each pixel block (PXB) may include a boosting capacitor and a reverse boosting capacitor for adjusting a voltage level of a common floating diffusion node.

The row driver 200 may operate the pixel blocks (PXBs) based on control signals received from a control circuit such as a timing controller 700. The row driver 200 may generate control signals (e.g., a transfer signal, a reset signal, a conversion gain signal, and a selection signal) for controlling the operation of transistors included in the pixel blocks (PXBs), and may output the control signals to the pixel blocks (PXBs). In addition, the row driver 200 may generate control signals (e.g., a boosting signal and a reverse boosting signal) for adjusting a voltage level of the common floating diffusion node, and may output the control signals to boosting capacitors and reverse boosting capacitors of the pixel blocks (PXBs).

The correlated double sampler (CDS) 300 may remove undesired offset values of the unit pixels using correlated double sampling.

The ADC 400 may convert the CDS signal received from the correlated double sampler 300 into a digital signal.

The output buffer 500 may temporarily store column-based data received from the ADC 300 based on the control of the timing controller 170.

The column driver 600 may select a column of the output buffer 500 under the control of the timing controller 700, and may sequentially output data temporarily stored in the selected column of the output buffer 500.

The timing controller 700 may generate signals for controlling the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

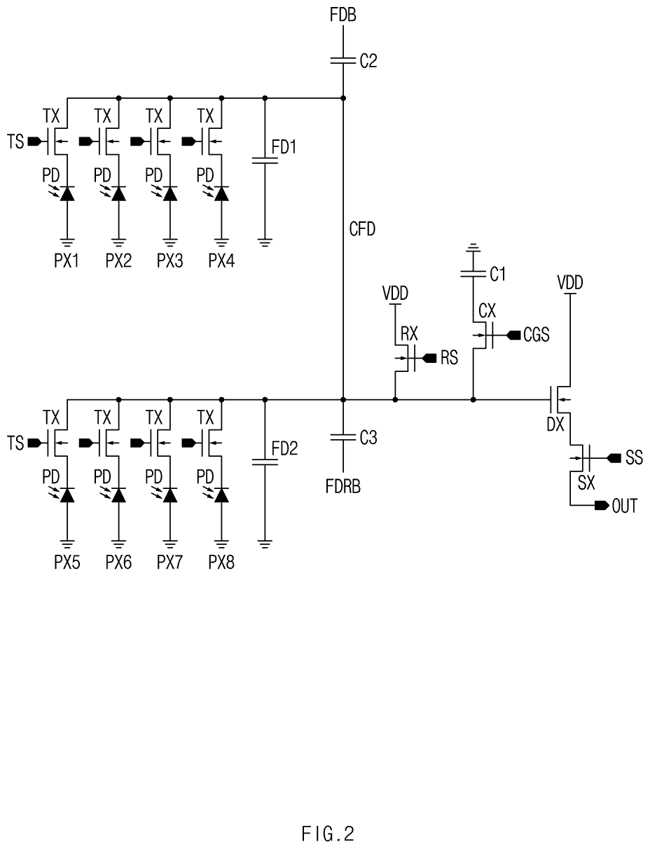

FIG. 2 is a circuit diagram illustrating an example of an equivalent circuit of a pixel block (PXB) according to an embodiment of the disclosed technology.

Referring to FIG. 2, a pixel block (PXB) may include unit pixels (PX1˜PX8 ), floating diffusion regions (FD1, FD2), a source follower transistor (DX), a selection transistor (SX), a reset transistor (RX), a conversion gain transistor (CX), a conversion gain capacitor (C1), a boosting capacitor (C2), and a reverse boosting capacitor (C3).

Each of the unit pixels (PX1˜PX8 ) may include a photoelectric conversion element (PD) that generates photocharges in response to incident light, and a transfer transistor (TX) that transfers photocharges generated by the photoelectric conversion element (PD) to the corresponding floating diffusion region (FD1, FD2) based on a transfer signal (TS).

The photoelectric conversion element (PD) may be implemented as a photodiode, a phototransistor, a photogate, a pinned photodiode, or a combination thereof. One terminal of each of the transfer transistors (TX) may be connected to a corresponding photoelectric conversion element (PD), and the other terminal of each transfer transistor (TX) may be connected to floating diffusion regions (FD1, FD2).

The floating diffusion regions (FD1, FD2) may store photocharges transferred by the transfer transistors (TX) from the photoelectric conversion element (PD). The floating diffusion region (FD1) may be connected to the transfer transistors (TX) of the unit pixels (PX1˜PX4) to receive and store photocharges from the unit pixels (PX1˜PX4), and the other floating diffusion region (FD2) may be connected to the transfer transistors (TX) of the unit pixels (PX5˜PX8) to receive and store photocharges from the unit pixels (PX5˜PX8).

The floating diffusion regions (FD1, FD2) may be connected to each other through a conductive line to form or effectuate a common floating diffusion node (CFD) for the two floating diffusion regions (FD1, FD2). The common floating diffusion node (CFD) may be connected to a gate terminal of the source follower transistor (DX), one terminal of the reset transistor (RX), and one terminal of the conversion gain transistor (CX) so that the photocharges generated by the unit pixels (PX1˜PX8 ) and collected in the floating diffusion regions (FD1, FD2) can be read out via a selection transistor (SX) connected to the source follower transistor (DX).

The reset transistor (RX) may be connected to a power-supply voltage (VDD) and the common floating diffusion node (CFD). The reset transistor (RX) may initialize the common floating diffusion node (CFD) to a power-supply voltage (VDD) level based on a reset signal (RS).

The conversion gain transistor (CX) may be connected to the conversion gain capacitor (C1) and the common floating diffusion node (CFD). The conversion gain transistor (CX) may selectively connect the conversion gain capacitor (C1) to the common floating diffusion node (CFD) based on a conversion gain signal (CGS), and may adjust capacitance of the common floating diffusion node (CFD).

The source follower transistor (DX) may be connected to the power-supply voltage (VDD) and the selection transistor (SX). The source follower transistor (DX) may be connected to the common floating diffusion node (CFD) through a gate terminal thereof, and may output a signal corresponding to a voltage magnitude of the common floating diffusion node (CFD).

The selection transistor (SX) may be connected between the source follower transistor (DX) and the output node (OUT). The selection transistor (SX) may output a signal output from the source follower transistor (DX) to the output node (OUT) based on a selection signal (SS). The signal output from the selection transistor (SX) may be transmitted to the CDS 300 through a column line.

The boosting capacitor (C2) and reverse boosting capacitor (C3) are coupled to the common floating diffusion node (CFD) to modify the voltage level of the common floating diffusion node (CFD) for improved imaging sensing operations such as reducing the undesired effects of the dark currents due to the fixed pattern noise or other sources caused by differences in hardware variations inherently present in different unit pixels and the improved linear responses of the source follower (DX) in the readout. The boosting capacitor (C2) may be connected to a boosting node to which a boosting signal (FDB) is applied. The boosting capacitor (C2) may increase the voltage level of the common floating diffusion node (CFD) upon receiving the boosting signal (FDB) through the boosting node. The boosting signal (FDB) may be applied to the boosting capacitor (C2) through the boosting node when photocharges accumulated in the photoelectric conversion element (PD) are transferred to the floating diffusion node (FD1 or FD2).

The reverse boosting capacitor (C3) may be connected to a reverse boosting node to which a reverse boosting signal (FDRB) is applied. The reverse boosting capacitor (C3) may decrease the voltage level of the common floating diffusion node (CFD) upon receiving the reverse boosting signal through the reverse boosting node. The reverse boosting signal may be applied to the reverse boosting capacitor (C3) before or after the boosting signal is applied. For example, the reverse boosting voltage may be applied to the reverse boosting capacitor (C3) during correlated double sampling.

The boosting signal (FDB) and the reverse boosting signal (FDRB) may have opposite phase. For example, the boosting signal (FDB) may have a positive voltage level that causes an increase in the voltage of the CFD, and the reverse boosting signal (FDRB) may have a negative voltage level that causes a decrease in the voltage of the CFD.

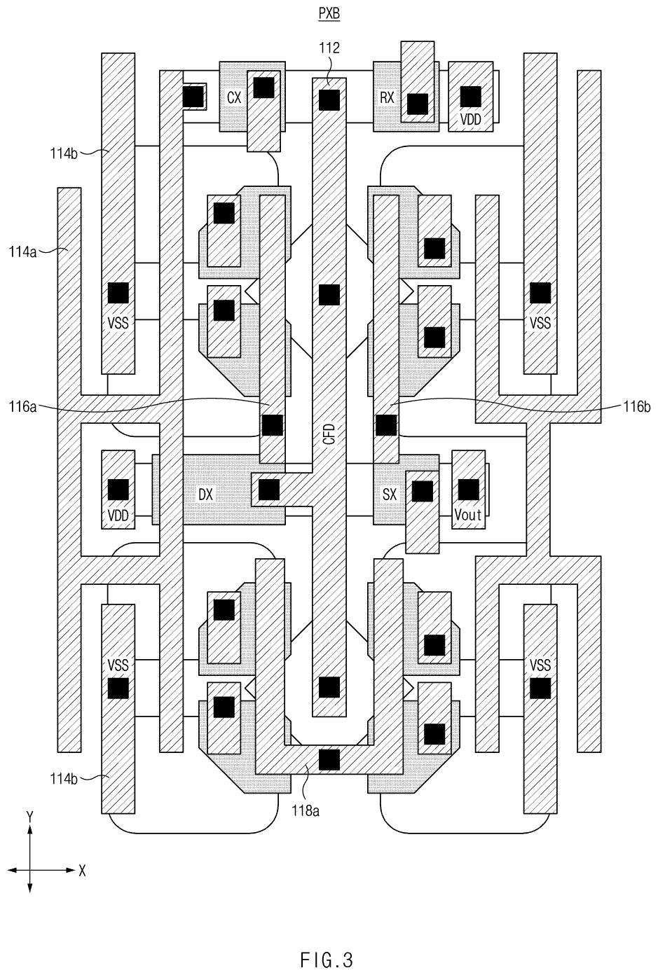

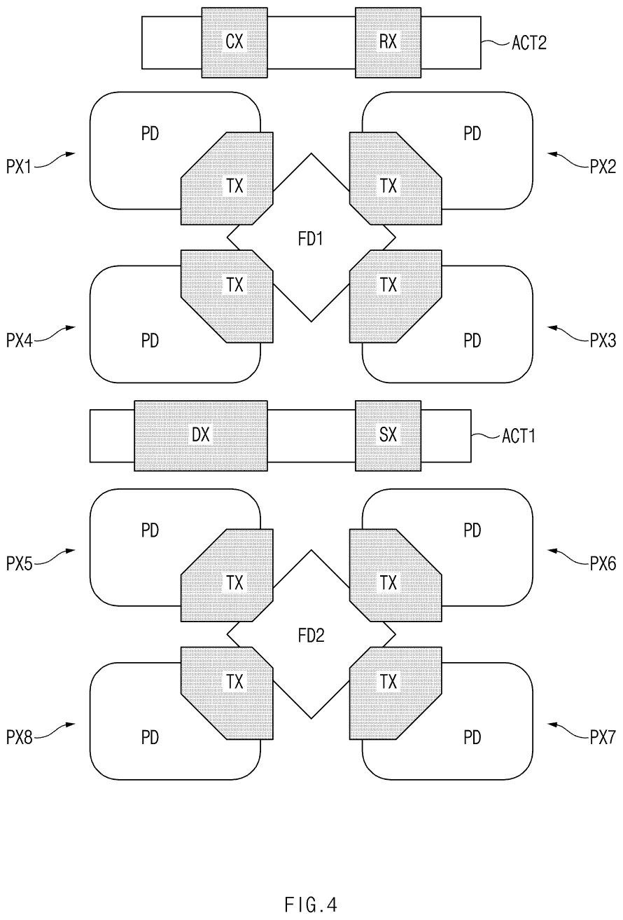

FIG. 3 is a schematic diagram illustrating an example structure of a pixel block based on some implementations of the disclosed technology. FIG. 4 is a plan view illustrating an example of a layout structure of photoelectric conversion elements, floating diffusion regions, and transistors shown in FIG. 3 according to an embodiment of the disclosed technology. In FIGS. 3 and 4, reference symbols (DX, SX, RX, TX, CX) for each transistor are indicated on the gate of the corresponding transistor for convenience of description.

Referring to FIGS. 3 and 4, a unit pixel block (PXB) may include an 8-shared pixel structure in which eight unit pixels (PX1˜PX8 ) share floating diffusion regions (FD1, FD2).

Four unit pixels (PX1˜PX4) may be arranged adjacently in a (2×2) structure including two rows and two columns, and may be arranged at different sides of the floating diffusion region (FD1) so as to share the floating diffusion region (FD1). For example, four unit pixels (PX1˜PX4) may be disposed to at least partially surround the floating diffusion region (FD1). Each of the unit pixels (PX1˜PX4) may include a photoelectric conversion region (PD) that converts incident light into electricity to generate photocharges, and a transfer transistor (TX) that is commonly connected to the floating diffusion region (FD1) and transmits photocharges generated by the photoelectric conversion region (PD) to the floating diffusion region (FD1) based on a transfer signal.

Four unit pixels (PX5˜PX8) may be arranged adjacently in a (2×2) structure, and may be arranged at different sides of the floating diffusion region (FD2), so that the four unit pixels (PX5˜PX8) may share the floating diffusion region (FD2). For example, four unit pixels (PX1˜PX4) may be disposed to at least partially surround the floating diffusion region (FD1). Each of the unit pixels (PX5˜PX8) may include a photoelectric conversion region (PD) and a transfer transistor (TX). The transfer transistor (TX) may be commonly connected to the floating diffusion region (FD2), and may transfer photocharges generated by the photoelectric conversion region (PD) to the floating diffusion region (FD2) based on a transfer signal.

As shown in FIG. 3, the conductive line 112 may be disposed over the floating diffusion regions (FD1, FD2) so as to overlap with the floating diffusion regions (FD1, FD2). When the floating diffusion regions (FD1, FD2) are disposed along a second direction (e.g., Y-axis direction), the conductive line 112 may extend along the second direction. The floating diffusion regions (FD1, FD2) may be electrically connected to each other to form a common floating diffusion node (CFD). The common floating diffusion node (CFD) may be electrically connected to one terminal (source/drain region) of the reset transistor (RX), one terminal (source/drain region) of the conversion gain transistor (CX), and the gate of the source follower transistor (DX) through a conductive line 112.

The unit pixels (PX1˜PX4) and the unit pixels (PX5˜PX8) may be spaced apart from each other in the second direction (e.g., Y-axis direction). The source follower transistor (DX) and the selection transistor (SX) may be disposed between the unit pixels (PX1˜PX4) and the unit pixels (PX5˜PX8). The source follower transistor (DX) and the selection transistor (SX) may be arranged in one line in a first direction (e.g., X-axis direction) and may share an active region (ACT1).

A conversion gain transistor (CX) and a reset transistor (RX) may be disposed at one side of the unit pixels (PX1˜PX4) in the second direction. The conversion gain transistor (CX) and the reset transistor (RX) may be arranged in one line in the first direction, and may share an active region (ACT2).

As shown in FIG. 3, a conductive line 114a may be connected to one terminal of the conversion gain transistor (CX). The conductive line 114a may be disposed at one side of the boosting electrode 116a and the reverse boosting electrode 118a in the first direction, while the boosting electrode 116a and the reverse boosting electrode 118a are disposed in the second direction. The conductive line 114a may be formed to be located adjacent to the conductive lines 114b connected to a ground voltage (VSS) and may be shaped, for example, to at least partially surround the conductive lines 114b. The conductive line 114a, the conductive lines 114b, and an insulation layer disposed between the conductive line 114a and the conductive lines 114b may constitute the conversion gain capacitor (C1) shown in FIG. 2.

Boosting electrodes (116a, 116b) for boosting the common floating diffusion node (CFD) may be disposed on at least one side of the conductive line 112 in the first direction. For example, the boosting electrodes (116a, 116b) may be arranged adjacent to the conductive line 112 on both sides of the conductive line 112 in the first direction. The boosting electrodes (116a, 116b) may be formed symmetrically to each other and may extend in the second direction.

The boosting electrode 116a may be disposed to overlap the unit pixels (PX1, PX4) and the floating diffusion region (FD1), and the boosting electrode 116b may be disposed to overlap the unit pixels (PX2, PX3) and the floating diffusion region (FD1). The boosting electrodes (116a, 116b) may be connected to a boosting node, and may receive a boosting signal (FDB) from the row driver 200.

The conductive line 112 may be connected to the floating diffusion regions (FD1, FD2) and the boosting electrodes (116a, 116b) may be connected to the boosting node, so that the conductive line 112, the boosting electrodes (116a, 116b), and the insulation layer disposed between the conductive line 112 and the boosting electrodes (116a, 116b) may form the boosting capacitor (C2) shown in FIG. 2.

In the present embodiment, the conductive line 112 forming the common floating diffusion node (CFD) may be used as an upper electrode of the boosting capacitor (C2), and the boosting electrodes (116a, 116b) that are coupled to the conductive line 112 while being adjacent to the conductive line 112 may be used as a lower electrode of the boosting capacitor (C2).

The reverse boosting electrode 118a may be spaced apart from the boosting electrodes (116a, 116b) in the second direction, and may be arranged adjacent to the conductive line 112. In some implementations, the reverse boosting electrodes 118a may be disposed at different locations, such as sides, of a portion of the conductive line 112. For example, the reverse boosting electrodes 118a may be disposed to at least partially surround one end of the conductive line 112. For example, the reverse boosting electrode 118a may be formed to at least partially surround one end of the conductive line 112 in a “U” shape while being located to overlap the unit pixels (PX5˜PX8) and the floating diffusion region (FD2). The reverse boosting electrode 118a may be electrically isolated from the boosting electrodes (116a, 116b), and may be connected to a reverse booting node to receive a reverse boosting signal (FDRB) from the row driver 200.

The conductive line 112 is connected to the floating diffusion regions (FD1, FD2) and the reverse boosting electrode 118a is connected to the reverse boosting node, so that the conductive line 112, the reverse boosting electrode 118a, and the insulation layer disposed between the conductive line 112 and the reverse boosting electrode 118a may constitute the reverse boosting capacitor (C3) shown in FIG. 2.

In the present embodiment, the conductive line 112 that forms the common floating diffusion node (CFD) by interconnecting the floating diffusion regions (FD1, FD2) may be used as an upper electrode of the reverse boosting capacitor (C3), and the reverse boosting electrode 118a adjacent to the conductive line 112 may be used as a lower electrode of the reverse boosting capacitor (C3). The reverse boosting electrode 118a may have the same critical dimension (CD) as each of the boosting electrodes (116a, 116b) or may have a larger critical dimension (CD) than each of the boosting electrodes (116a, 116b).

As shown in FIG. 3, the boosting electrodes (116a, 116b) may be disposed at both sides of the conductive line 112 while overlapping the unit pixels (PX1˜PX4), and the reverse boosting electrode 118a may be formed at different sides of the end of the conductive line 112 while overlapping the unit pixels (PX5˜PX8).

In some implementations, the arrangements of the reverse boosting electrode and the boosting electrode can be interchanged. For example, unlike the example as shown in FIG. 3, the reverse boosting electrodes may be disposed at both sides of the conductive line 112 while overlapping the unit pixels (PX1˜PX4), and the boosting electrode may be disposed to surround the end of the conductive line 112 while overlapping the unit pixels (PX5˜PX8). In this particular example as illustrated, the conductive lines (116a, 116b) may operate as the reverse boosting electrodes for receiving a reverse boosting signal, and the conductive line 118a may operate as the boosting electrode for receiving a boosting signal.

In some implementations, the conductive lines (112, 114a, 114b), the boosting electrodes (116a, 116b), and the reverse boosting electrode 118a may be formed in the same layer (e.g., M1 layer).

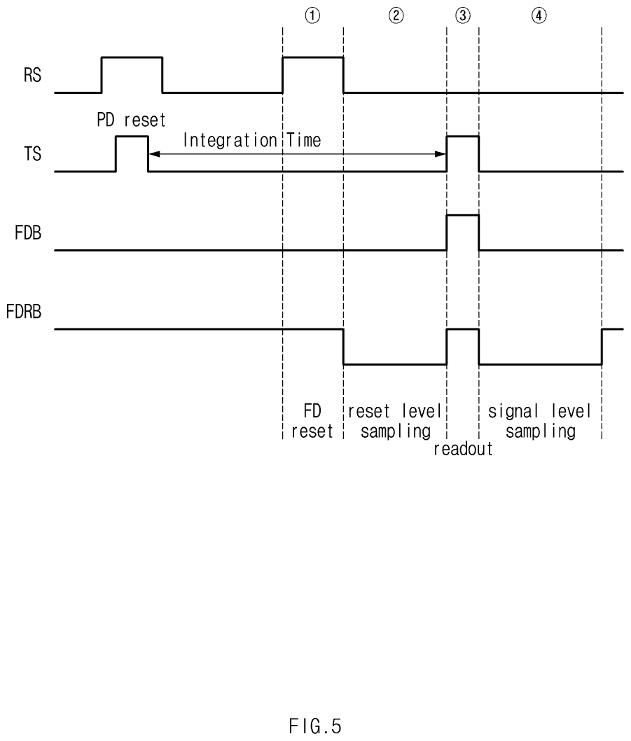

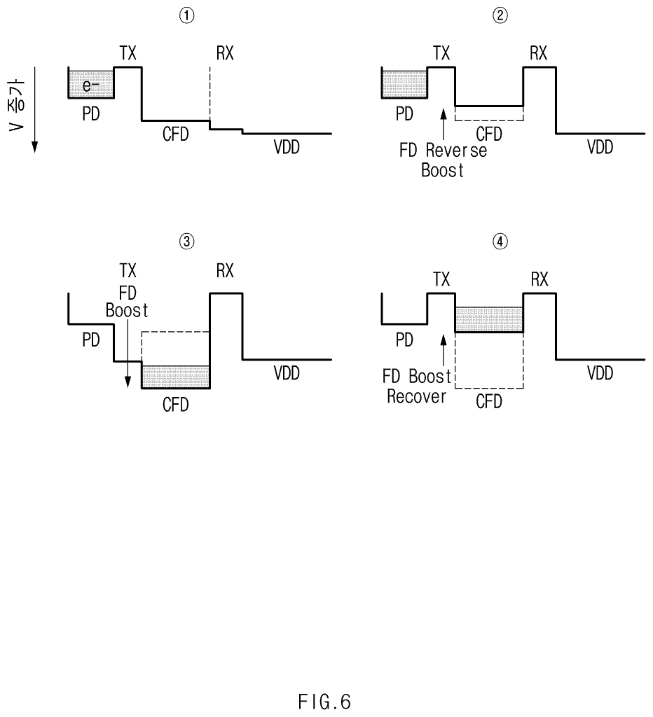

FIG. 5 is a timing diagram illustrating example operations of the image sensing device according to an embodiment of the disclosed technology. FIG. 6 is a schematic diagram illustrating potential changes of the photoelectric conversion element (PD), the transfer transistor (TX), the common floating diffusion node (CFD), and the reset transistor (RX) for use in the operation sections (\textcircled{1}, \textcircled{2}, \textcircled{3}, \textcircled{4}) of FIG. 5 according to an embodiment of the disclosed technology.

Referring to FIGS. 5 and 6, when the reset signal (RS) is activated to a high level and the reset transistor (RX) is turned on, the power-supply voltage (VDD) is applied to the common floating diffusion node (CFD) through the conductive line 112, so that the floating diffusion regions (FD1, FD2) may be reset.

When the transfer signal (TS) is activated to a high level while the reset signal (RS) is activated, the transfer transistor (TX) is turned on, so that the photoelectric conversion element (PD) of the unit pixel (PX1) may also be reset.

Thereafter, when the transfer signal (TS) is deactivated, photocharges generated in response to incident light may be accumulated in the photoelectric conversion element (PD). A time section from a start time point where the photoelectric conversion element (PD) is reset and the transfer signal (TS) is then reactivated to a readout time point where photocharges accumulated in the photoelectric conversion element (PD) are transferred to the floating diffusion region (FD1) will hereinafter be referred to as an integration time.

After the integration time starts, when the reset signal (RS) is reactivated and the reset transistor (RX) is turned on, the power-supply voltage (VDD) is applied to the common floating diffusion node (CFD) so that the floating diffusion regions (FD1, FD2) can be reset (see \textcircled{1}).

At this time, as shown in FIG. 6, photocharges (electrons) accumulated in the photoelectric conversion element (PD) are not transferred to the common floating diffusion node (CFD) due to a potential barrier caused by the transfer transistor (TX).

Next, the reset signal (RS) may be deactivated and reset level sampling for correlated double sampling may be performed (see \textcircled{2}).

During the reset level sampling period (\textcircled{2}), the row driver 200 may activate the reverse boosting signal (FDRB) to a low level (e.g., a negative voltage level), and may transmit the activated reverse boosting signal (FDRB) to the reverse boosting electrode 118a. When the reverse boosting signal (FDRB) of a negative voltage level is applied to the reverse boosting electrode 118a, reverse boosting in which the voltage level of the common floating diffusion node (CFD) decreases can be performed as shown in FIG. 6.

Subsequently, when the transfer signal (TS) is activated, the transfer transistor (TX) is turned on, so that a readout operation in which photocharges accumulated in the photoelectric conversion element (PD) are transferred to the common floating diffusion node (CFD) may be performed (\textcircled{3}).

During the readout period (\textcircled{3}), the row driver 200 may deactivate the reverse boosting signal (FDRB) and may activate the boosting signal (FDB) to a high level (positive voltage level), so that the boosting signals (FDB) can be applied to the boosting electrodes (116a, 116b).

As the boosting signal (FDB) is activated, boosting in which the voltage level of the common floating diffusion node (CFD) increases may be performed as shown in FIG. 6, thereby increasing the transmission efficiency of photocharges.

Subsequently, when the readout operation is completed, the transfer signal (TS) may be deactivated, and signal level sampling for correlated double sampling may be performed (\textcircled{4}).

During the signal level sampling period (\textcircled{4}), the row driver 200 may deactivate the boosting signal (FDB) and may activate the reverse boosting signal (FDRB) to a low level again, so that the activated reverse boosting signal (FDRB) can be applied to the reverse boosting electrode 118a. When the reverse boosting signal (FDRB) having a negative voltage level is applied again to the reverse boosting electrode 118a, reverse boosting in which the voltage level of the common floating diffusion node (CFD) decreases to the same level as in section (\textcircled{2}) may be performed as shown in FIG. 6.

A plurality of pixel signals output from a plurality of unit pixels may have deviations due to unique characteristics (e.g., fixed pattern noise (FPN) etc.) of each pixel, and/or may have deviations caused by a difference in characteristics between circuits (e.g., transistors) within a pixel block (PXB) for outputting pixel signals.

In order to compensate for such deviations between the plurality of pixel signals, the CDS 300 may perform correlated double sampling that obtains a reset component (e.g., a reset voltage) of the pixel signal and a signal component (e.g., a sensing voltage) of the pixel signal and extracts a difference between the reset component and the signal component as a valid signal component. At this time, reset level sampling for obtaining the reset component may be performed before the readout operation, and signal level sampling for obtaining the signal component may be performed after the readout operation.

During such reset level sampling and such signal level sampling, when the common floating diffusion node (CFD) has a high voltage level, a large amount of dark leakage in which dark current flows from the semiconductor substrate into the floating diffusion regions (FD1, FD2) may occur, thereby increasing the possibility of occurrence of signal errors.

In the present embodiment, during correlated double sampling (reset level sampling and signal level sampling), the common floating diffusion node (CFD) may be reverse-boosted to lower the voltage level of the common floating diffusion node (CFD), so that the amount of dark current that will flow into the floating diffusion regions (FD1, FD2) due to dark leakage can be minimized. Accordingly, it is possible to prevent the voltage level of the common floating diffusion node (CFD) from fluctuating due to the dark current. In addition, a voltage swing width of the common floating diffusion node (CFD) is adjusted so that linearity of a source follower gain can be stably maintained.

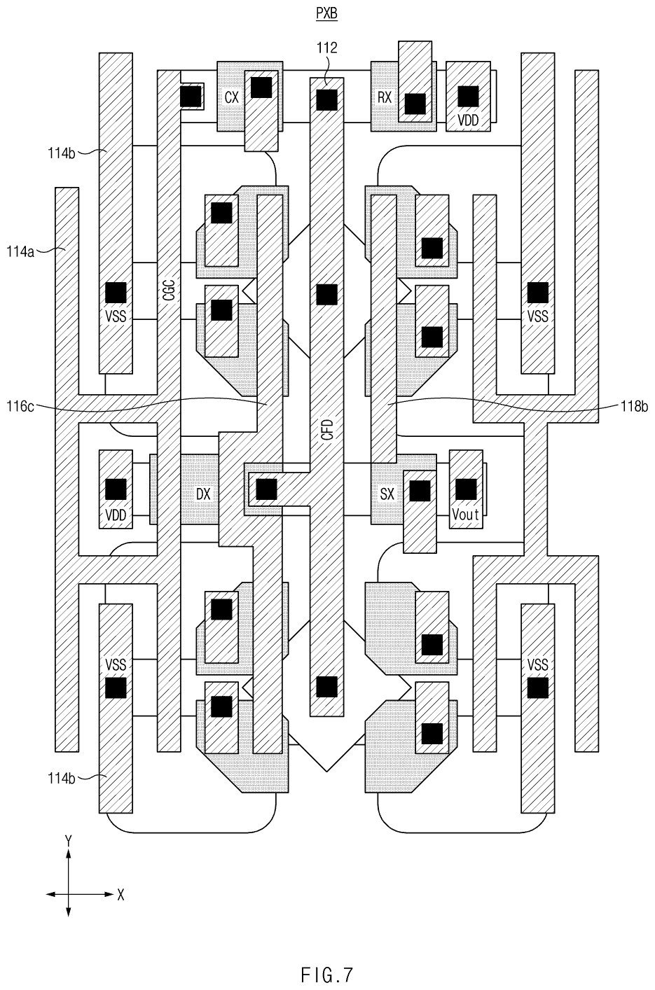

FIGS. 7 to 9 are schematic diagrams illustrating example structures of a boosting line and a reverse boosting line according to another embodiment of the disclosed technology.

The embodiments of FIGS. 7 to 9 differ from the embodiment of FIG. 3 in the structure of the boosting electrode and the reverse boosting electrode, and the remaining components other than the boosting electrode and the reverse boosting electrode may be formed in the same manner as the embodiment of FIG. 3. Therefore, in the following embodiments, description of the remaining components other than the boosting electrode and the reverse boosting electrode will herein be omitted for brevity.

Referring to FIG. 7, the boosting electrode 116c and the reverse boosting electrode 118b may be disposed at different sides of the conductive line 112, respectively. For example, the boosting electrode 116c may be disposed at one side of the conductive line 112 to overlap the unit pixels (PX1, PX4, PX5, PX8) and the floating diffusion regions (FD1, FD2). The reverse boosting electrode 118b may be disposed at the opposite side of the conductive line 112 to overlap the unit pixels (PX2, PX3) and the floating diffusion region (FD1).

In FIG. 7, the reverse boosting electrode 118b may extend in the second direction to overlap the unit pixels (PX2, PX3) and the floating diffusion region (FD1), and the boosting electrode 116c may extend in the second direction to overlap the unit pixels (PX1, PX4, PX5, PX8) and the floating diffusion regions (FD1, FD2). The reverse boosting electrode 118b may have a length relatively shorter than the boosting electrode 116c. the length measured in the second direction. However, the reverse boosting electrode 118b may also extend in the second direction so as to overlap the unit pixels (PX2, PX3, PX6, PX7) and the floating diffusion regions (FD1, FD2).

In some implementations, the locations where the boosting electrode 116c and the reverse boosting electrode 118b are disposed may be interchanged. For example, the boosting electrode 116c may be disposed at one side (e.g., the right side in FIG. 7) of the conductive line 112 so as to overlap the unit pixels (PX2, PX3, PX6, PX7) and the floating diffusion regions (FD1, FD2), and the reverse boosting electrode 118b may be disposed at the opposite side (e.g., the left side in FIG. 7) of the conductive line 112 so as to overlap the unit pixels (PX1, PX4) and the floating diffusion region (FD1).

In some implementations, the shapes of the boosting electrode 116c and the reverse boosting electrode 118b may be interchanged. For example, the conductive line 116c may have a shape same as the shape of the reverse boosting electrode as shown in FIG. 7, and the conductive line 118b may have a shape same as the shape of the boosting electrode as shown in FIG. 7.

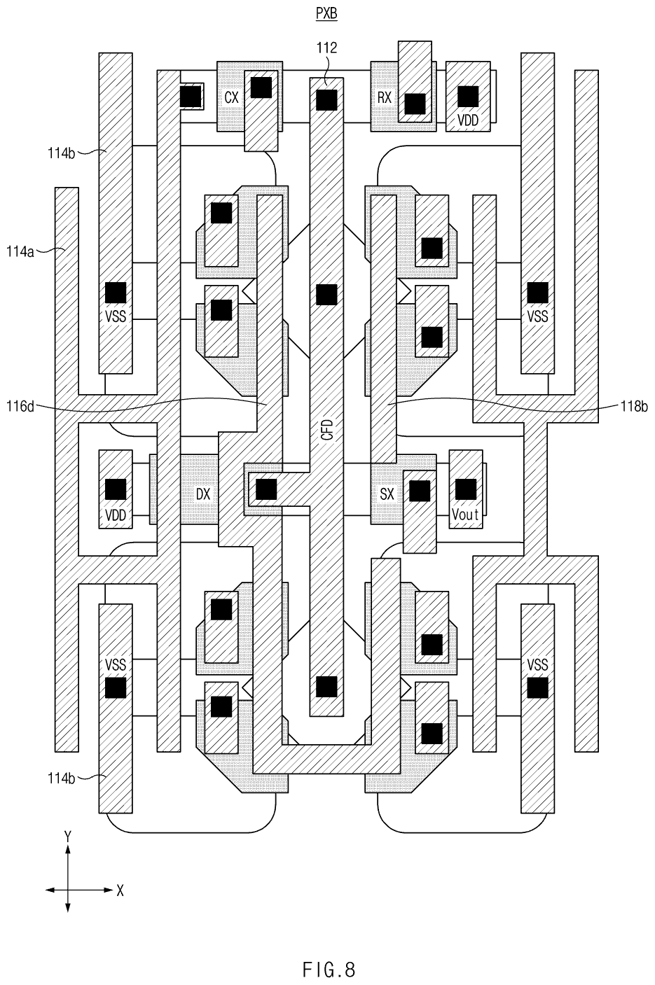

FIG. 8 is a schematic diagram illustrating an example structure of a boosting line and a reverse boosting line according to another embodiment of the disclosed technology. Referring to FIG. 8, the boosting electrode 116d may have further extended portions. As compared to the boosting electrode 116c in FIG. 7, the boosting electrode 116d in FIG. 8 may be disposed at different sides of the conductive line 112. For example, the boosting electrode 116d may have portions disposed at different sides of one end of the conductive line 112 to at least partially surround the one end of the conductive line 112. In the example, the boosting electrode 116d have a portion that is disposed at one side of the conductive line 112 in the first direction and overlaps the unit pixels PX1, PX4, PX5 and PX8 and another portion that is disposed at the different side of the conductive line 112 in the first direction and overlaps the unit pixels PX6 and PX7. For example, the boosting electrode 116d may be formed to at least partially surround one end of the conductive line 112 while being disposed at one side of the conductive line 112 in the first direction so as to overlap the unit pixels (PX1, PX4, PX5˜PX8) and the floating diffusion regions (FD1, FD2).

The reverse boosting electrode 118b may be disposed at the opposite side of the conductive line 112 so as to overlap the unit pixels (PX2, PX3) and the floating diffusion region (FD1), as shown in FIG. 7.

The position of the boosting electrode 116d and the position of the reverse boosting electrode 118b may be exchanged with each other. In addition, the shape of the boosting electrode 116d and the shape of the reverse boosting electrode 118b may be formed in opposite directions. For example, the conductive line 116d may become the reverse boosting electrode, and the conductive line 118b may become the boosting electrode.

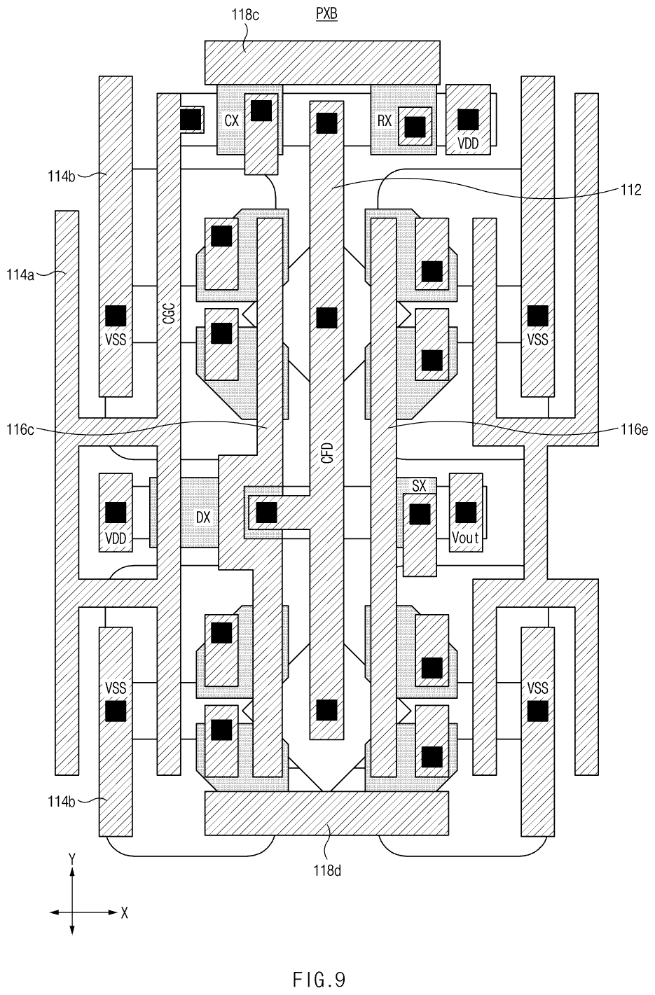

Referring to FIG. 9, the boosting electrodes (116c, 116e) may be disposed on at least one side of the conductive line 112 in the first direction. For example, the boosting electrode 116c may be disposed at one side of the conductive line 112 to overlap the unit pixels (PX1, PX4, PX5, PX8) and the floating diffusion regions (FD1, FD2), and the boosting electrode 116e may be disposed at the opposite side of the conductive line 112 to overlap the unit pixels (PX2, PX3, PX6, PX7) and the floating diffusion regions (FD1, FD2).

The reverse boosting electrodes (118c, 118d) may be disposed on at least one side of the conductive line 112 in the second direction. For example, the reverse boosting electrodes (118c, 118d) may be disposed at both sides of the conductive line 112 adjacent to both ends of the conductive line 112.

The positions of the boosting electrodes (116c, 116e) and the positions of the reverse boosting electrodes (118c, 118d) may be exchanged. For example, the boosting electrodes (116c, 116d) may be disposed at both sides of the conductive line 112 in the second direction, and the reverse boosting electrodes (118c, 118d) may be disposed at both sides of the conductive line 112 in the first direction.

Although the above-described embodiments have disclosed only the example cases where the pixel block (PXB) has an 8-shared pixel structure for convenience of description, it is obvious that the boosting electrode and the reverse boosting electrode can also be applied even when the pixel block (PXB) has a 4-shared pixel structure.

As is apparent from the above description, the image sensing device based on some implementations of the disclosed technology can minimize occurrence of signal errors caused by dark leakage source.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
at least one floating diffusion region configured to store photocharges;
a first conductive line electrically connected to the at least one floating diffusion region;
at least one boosting electrode configured to receive a boosting signal and disposed adjacent to the first conductive line; and
at least one reverse boosting electrode disposed adjacent to the first conductive line and configured to receive a reverse boosting signal having an opposite phase to the boosting signal.

2. The image sensing device according to claim 1, wherein:
the at least one boosting electrode is disposed at two sides of the first conductive line in a first direction.

3. The image sensing device according to claim 2, wherein:
the at least one reverse boosting electrode is disposed to at least partially surround an end portion of the first conductive line.

4. The image sensing device according to claim 2, wherein:
the at least one reverse boosting electrode is disposed at two sides of the first conductive line in a second direction intersecting the first direction.

5. The image sensing device according to claim 1, wherein:
the at least one boosting electrode is disposed at one side of the first conductive line in a first direction; and
the at least one reverse boosting electrode is disposed at an opposite side of the first conductive line in the first direction.

6. The image sensing device according to claim 5, wherein:
the at least one boosting electrode or the at least one reverse boosting electrode extends to at least partially surround an end portion of the first conductive line.

7. The image sensing device according to claim 1, wherein the at least one floating diffusion region includes:
a first floating diffusion region; and
a second floating diffusion region spaced apart from the first floating diffusion region, and electrically connected to the first floating diffusion region through the first conductive line.

8. The image sensing device according to claim 7, wherein:
the at least one boosting electrode is disposed at two sides of the first conductive line to overlap the first floating diffusion region; and
the reverse boosting electrode is disposed to at least partially surround an end portion of the first conductive line and overlapping the second floating diffusion region.

9. The image sensing device according to claim 7, wherein:
the at least one boosting electrode is disposed at one side of the first conductive line in a first direction; and
the at least one reverse boosting electrode is disposed at an opposite side of the first conductive line in the first direction.

10. The image sensing device according to claim 9, wherein:
the at least one boosting electrode or the at least one reverse boosting electrode extends to at least partially surround an end portion of the first conductive line and overlapping the first floating diffusion region and the second floating diffusion region.

11. The image sensing device according to claim 7, wherein:
the at least one boosting electrode is disposed at two sides of the first conductive line and overlapping the first floating diffusion region and the second floating diffusion region; and
the reverse boosting electrode is disposed at two sides of the first conductive line in a second direction perpendicular to the first direction.

12. The image sensing device according to claim 1, further comprising:
a row driver configured to output the boosting signal and the reverse boosting signal,
wherein the row driver is configured to activate the reverse boosting signal during a correlated double sampling.

13. The image sensing device according to claim 1, further comprising:
a conversion gain transistor disposed at one side of the at least one floating diffusion region, and electrically connected to the first conductive line through a first terminal of the conversion gain transistor;
a second conductive line disposed at one side of the boosting electrode and the reverse boosting electrode in a first direction, and electrically connected to a ground voltage; and
a third conductive line disposed adjacent to the second conductive line and at least partially surrounding the second conductive line, the third conductive line electrically connected to a second terminal of the conversion gain transistor.

14. An image sensing device comprising:
a first floating diffusion region and a second floating diffusion region, each of the first floating diffusion region and the second floating diffusion region configured to store photocharges;
a plurality of first unit pixels disposed at different locations adjacent to the first floating diffusion region, and configured to generate the photocharges that are generated through a photoelectric conversion in each first unit pixel and are transferred to the first floating diffusion region;
a plurality of second unit pixels disposed at different locations adjacent to the second floating diffusion region, and configured to generate photocharges that are generated through a photoelectric conversion in each second unit pixel and are transferred to the second floating diffusion region;
a first conductive line configured to electrically interconnect the first floating diffusion region and the second floating diffusion region to form a common floating diffusion node;
at least one boosting electrode disposed adjacent to the first conductive line, and configured to receive a boosting signal; and
at least one reverse boosting electrode disposed adjacent to the first conductive line, and configured to receive a reverse boosting signal having an opposite phase to the boosting signal.

15. The image sensing device according to claim 14, wherein the at least one boosting electrode includes:
a first boosting electrode disposed at one side of the first conductive line in a first direction and overlapping the first and fourth unit pixels; and
a second boosting electrode disposed at an opposite side of the first conductive line in the first direction and overlapping the second and third unit pixels.

16. The image sensing device according to claim 15, wherein:
the at least one reverse boosting electrode is disposed to at least partially surround an end portion of the first conductive line while overlapping the fifth to eighth unit pixels.

17. The image sensing device according to claim 15, wherein:
the first boosting electrode extends in a second direction perpendicular to the first direction and overlapping the fifth and eighth unit pixels;
the second boosting electrode extends in the second direction and overlaps the sixth and seventh unit pixels;
the at least one reverse boosting electrode is disposed at two sides of the first conductive line in the second direction.

18. The image sensing device according to claim 14, wherein:
the at least one boosting electrode is disposed at one side of the first conductive line to overlap the first and fourth unit pixels; and
the at least one reverse boosting electrode is disposed at one side of the first conductive line to overlap the second and third unit pixels.

19. The image sensing device according to claim 18, wherein:
the at least one boosting electrode extends to overlap the fifth and eighth unit pixels.

20. The image sensing device according to claim 19, wherein:
the at least one boosting electrode extends to at least partially surround an end portion of the first conductive line.
